(19) United States
(12) Patent Application Publication
(10) Pub. No.: US 2024/0306405 A1
(43) Pub. Date: Sep. 12, 2024

(54) SEMICONDUCTOR STORAGE DEVICE

(71) Applicant: Kioxia Corporation, Tokyo (JP)

(72) Inventors: Junichi SATO, Yokohama Kanagawa (JP); Kazuto UEHARA, Sagamihara Kanagawa (JP); Yuuta SANO, Yokosuka Kanagawa (JP); Yoshihiro SAEKI, Yokohama Kanagawa (JP)

(21) Appl. No.: 18/590,778

(22) Filed: Feb. 28, 2024

(30) Foreign Application Priority Data
Mar. 10, 2023 (JP) 2023-037935

(51) Int. Cl. H10B 80/00; H01L 25/065

(52) U.S. Cl. CPC H10B 80/00; H01L 25/0657; H01L 2225/06506; H01L 2225/06562; H01L 2225/06582

(57) ABSTRACT

A semiconductor storage device comprises a memory chip including first and second control signal pads to which first and second control signals are to be input, respectively, a data signal pad to and from which a data signal is to be input and output, and a control circuit. The control circuit stores data in the data signal in a data register, when the first and second control signals are at a first state, stores data in the data signal in a command register, when the first control signal is at a second state and the second control signal is at the first state, stores data in the data signal in an address register, when the first control signal is at the first state and the second control signal is at the second state, and outputs status data when the first and second control signals are at the second state.

### CROSS-REFERENCE TO RELATED APPLICATION(S)

This application is based upon and claims the benefit of priority from Japanese Patent Application No. 2023-037935, filed Mar. 10, 2023, the entire contents of which are incorporated herein by reference.

### FIELD

Embodiments described herein relate generally to a semiconductor storage device.

### BACKGROUND

A semiconductor storage device including a memory chip that has a first signal pad to which a first signal is input, a second signal pad to which a second signal is input, a data signal pad to and from which a data signal is input and output, and a memory cell array including a plurality of memory cell transistors, is known.

### DESCRIPTION OF THE DRAWINGS

FIG. 1 is a schematic block diagram showing a configuration of a memory system that is configured according to a first embodiment.

FIG. 2 is a schematic perspective view showing a configuration example of a memory package in the memory system of FIG. 1.

FIG. 3 is a schematic block diagram showing a configuration example of a controller in the memory package of FIG. 2.

FIG. 4 is a schematic block diagram showing a configuration of a memory die in the memory package of FIG. 2.

FIG. 5 is a schematic circuit diagram showing a configuration of a part of the memory die.

FIG. 6 is a schematic perspective view showing a configuration of a part of the memory die.

FIG. 7 is a schematic block diagram showing a configuration of a part of the memory die.

FIG. 8 is a truth table showing the roles of external control terminals of the memory die.

FIG. 9 is a schematic waveform diagram showing a read operation of the memory die.

FIG. 10 is a schematic waveform diagram showing a data output operation of the memory die.

FIG. 11 is a schematic waveform diagram showing a write operation of the memory die.

FIG. 12 is a schematic waveform diagram showing a status read operation.

FIG. 13 is a schematic waveform diagram showing the write operation of the memory die.

FIG. 14 is a schematic waveform diagram showing a status read operation according to the first embodiment.

FIG. 15 is a schematic waveform diagram showing a write operation of the memory die according to the first embodiment.

FIG. 16 is a schematic block diagram showing Modification Example 1 of the first embodiment.

FIG. 17 is a schematic perspective view showing Modification Example 1 of the first embodiment.

FIG. 18 is a schematic waveform diagram showing Modification Example 1 of the first embodiment.

FIG. 19 is a schematic block diagram showing a second embodiment.

FIG. 20 is a schematic block diagram showing the second embodiment.

FIG. 21 is a schematic waveform diagram showing the second embodiment.

FIG. 22 is a schematic waveform diagram showing Modification Example 1 of the second embodiment.

FIG. 23 is a schematic block diagram showing another example of the second embodiment.

### DETAILED DESCRIPTION

Embodiments provide a semiconductor storage device that operates at high speed.

In general, according to one embodiment, a semiconductor storage device comprises a memory chip that includes a first control signal pad to which a first control signal is to be input, a second control signal pad to which a second control signal is to be input, a data signal pad to and from which a data signal is to be input and output, a memory cell array including a plurality of memory cell transistors, and a control circuit configured to control the memory chip based on the first and second control signals. The control circuit stores data in the data signal received through the data signal pad in a data register, when the first control signal is at a first state and the second control signal is at the first state, stores data in the data signal received through the data signal pad in a command register, when the first control signal is at a second state and the second control signal is at the first state, stores data in the data signal received through the data signal pad in an address register, when the first control signal is at the first state and the second control signal is at the second state, and outputs status data when the first control signal is at the second state and the second control signal is at the second state.

Next, the semiconductor storage device according to the embodiment will be described in detail with reference to the drawings. The following embodiment is merely an example, and is not intended to limit the present disclosure.

In addition, the term “semiconductor storage device” used in the present specification may mean a configuration including a memory die (also referred to as a memory chip) implemented in a memory card or an SSD, and a controller. The term “semiconductor storage device” may mean a configuration including a host computer such as a smartphone, a tablet terminal, and a personal computer.

In addition, the term “semiconductor storage device” used in the present specification may mean a memory die.

In the present specification, when a first configuration is said to be “electrically connected” to a second configuration, the first configuration may be directly connected to the second configuration, or the first configuration may be connected to the second configuration via a wiring, a semiconductor member, a transistor, or the like. For example, when three transistors are connected in series, the first transistor is “electrically connected” to the third transistor even though the second transistor is in an OFF state.

In the present specification, when the first configuration is said to be “connected between” the second configuration and the third configuration may mean that the first configuration, the second configuration, and the third configuration are connected in series and the second configuration is connected to the third configuration via the first configuration.

In the present specification, when a circuit or the like is said to cause two wirings and the like to be “electrically connected” may mean, for example, that the circuit or the like includes a transistor and the like, the transistor and the like are provided on a current path between the two wirings, and the transistor and the like enters into an ON state.

### First Embodiment

### Memory System 10

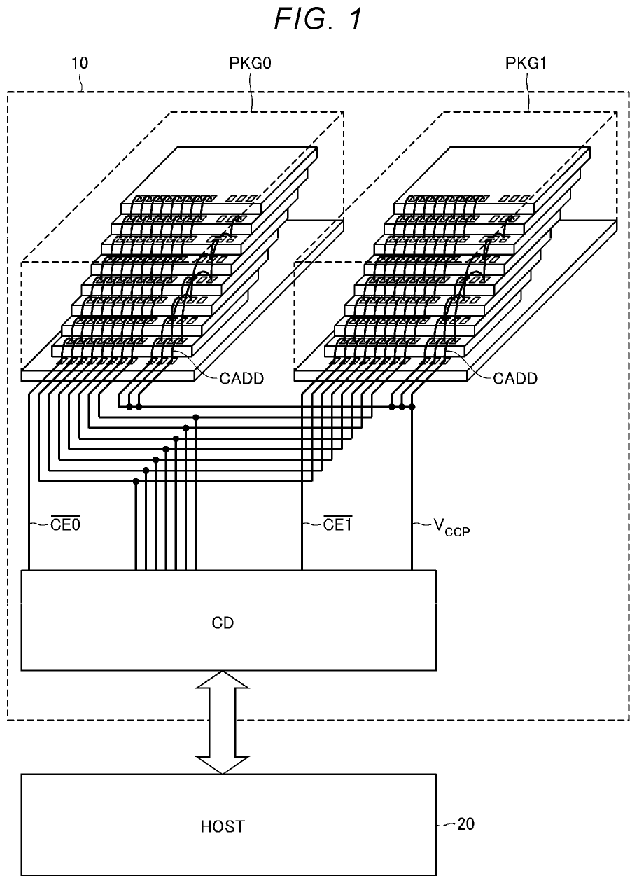

FIG. 1 is a schematic block diagram showing a configuration of a memory system 10 that is configured according to a first embodiment. The memory system 10 executes a read operation, a write operation, an erasing operation, and the like in accordance with a signal transmitted from a host computer 20. The memory system 10 is, for example, a memory card, SSD, or other system capable of storing user data. The memory system 10 includes a plurality of memory packages PKG0 and PKG1 that store user data, and a controller CD that is connected to the plurality of memory packages PKG0 and PKG1 and the host computer 20. In the following description, the memory packages PKG0 and PKG1 may be referred to as a memory package PKG.

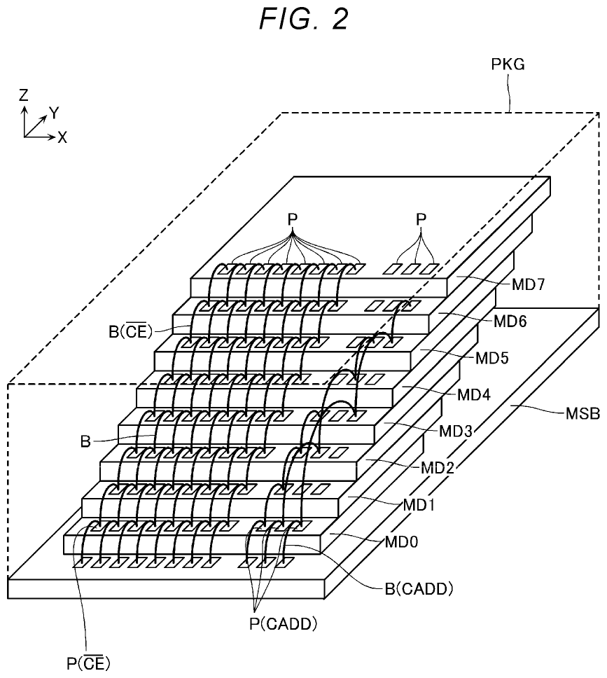

FIG. 2 is a schematic perspective view showing a configuration example of a memory package PKG in the memory system of FIG. 1. For convenience of description, a part of the configuration is omitted in FIG. 2.

As shown in FIG. 2, the memory package PKG includes a mounting substrate MSB and a plurality of memory dies MD0 to MD7 stacked on the mounting substrate MSB. A pad electrode P is provided in a region of an end portion of the upper surface of the mounting substrate MSB in the Y direction, and a part of another region of the upper surface of the mounting substrate MSB is adhered to the lower surface of the memory die MD0 via an adhesive or the like. The pad electrode P is provided in the region of the end portions of the upper surfaces of the memory dies MD0 to MD7 in the Y direction, and another region of the upper surfaces of the memory dies MD0 to MD7 is adhered to other memory dies MDI to MD7 via an adhesive or the like. The pad electrode P is provided in a region of an end portion of the upper surface of the memory die MD7 in the Y direction. In the following description, the memory dies MD0 to MD7 may be referred to as a memory die MD.

One of the plurality of pad electrodes P provided in the memory die MD functions as an external control terminal /CE. In addition, some of the plurality of pad electrodes P provided in the memory die MD function as chip address setting terminals CADD. The external control terminal /CE and the chip address setting terminal CADD are used to specify one memory die MD from the plurality of memory dies MD in the memory package PKG.

Among the plurality of pad electrodes P provided in the plurality of memory dies MD0 to MD7, the pad electrodes P functioning as the external control terminal /CE are commonly connected by the bonding wires B. In FIG. 1, the external control terminal /CE corresponding to the memory package PKG0 is indicated as the external control terminal /CE0, and the external control terminal /CE corresponding to the memory package PKG1 is indicated as the external control terminal /CE1. It is possible to input different signals to the external control terminal /CE0 and the external control terminal /CE1 from each other.

As shown in FIG. 2, among the plurality of pad electrodes P provided in the plurality of memory dies MD0 to MD7, the pad electrodes P functioning as the chip address setting terminal CADD are connected to the bonding wires B in different patterns. For example, in the example of FIG. 2, the first bonding wire B is connected to the memory dies MD0 to MD3 and is not connected to the memory dies MD4 to MD7. In addition, the second bonding wire B is connected to the memory dies MD0, MD2, MD4, and MD5, and is not connected to the memory dies MD1, MD3, MD6, and MD7. In addition, the third bonding wire B is connected to the memory dies MD0, MD3, MD5, and MD6, and is not connected to the memory dies MD1, MD2, MD4, and MD7. As shown in FIG. 1, all the chip address setting terminals CADD are connected to the voltage supply line V_{CCP} to which the power supply voltage is supplied.

As shown in FIG. 2, among the plurality of pad electrodes P provided in the plurality of memory dies MD0 to MD7, the pad electrodes P functioning as the rest of the terminals are commonly connected by the bonding wires B for each corresponding terminal. As shown in FIG. 1, the plurality of bonding wires B are commonly connected between the memory packages PKG0 and PKG1. It is possible to input different signals to the plurality of terminals from each other or to supply voltage to the plurality of terminals.

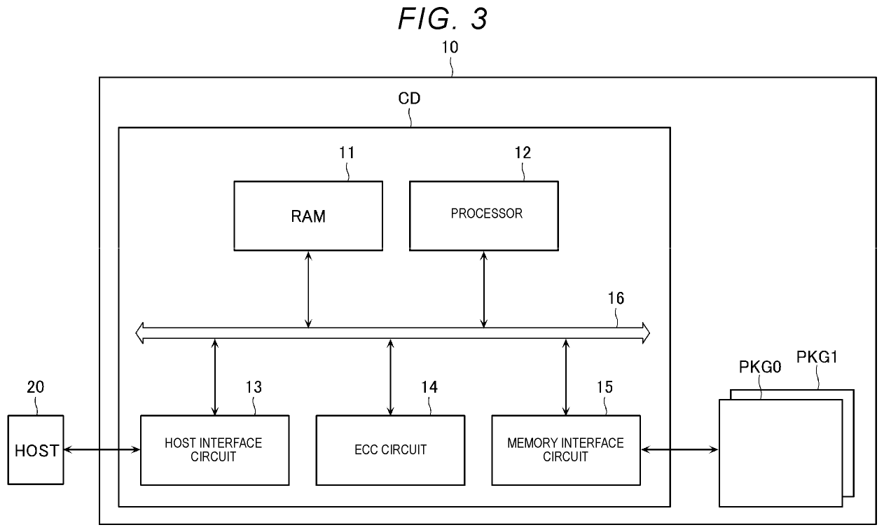

FIG. 3 is a schematic block diagram showing a configuration example of the controller CD according to the present embodiment. For convenience of description, a part of the configuration is omitted in FIG. 3.

The controller CD executes a read operation, a write operation, and the like of the memory packages PKG0 and PKG1 in accordance with an instruction from the host computer 20. The controller CD includes a random access memory (RAM) 11, a processor 12, a host interface circuit 13, an error check and correction (ECC) circuit 14, and a memory interface circuit 15. The RAM 11, the processor 12, the host interface circuit 13, the ECC circuit 14, and the memory interface circuit 15 are connected to each other via an internal bus 16.

The host interface circuit 13 outputs an instruction from the host computer 20, user data received from the host computer 20, and the like to the internal bus 16. The host interface circuit 13 transmits the user data output from the memory packages PKG0 and PKG1, the response from the processor 12, and the like to the host computer 20.

The memory interface circuit 15 executes control of a write operation and a read operation with respect to the memory packages PKG0 and PKG1 based on an instruction of the processor 12.

The processor 12 controls the controller CD. The processor 12 includes, for example, a central processing unit (CPU), a micro processing unit (MPU), and the like. When an instruction is received from the host computer 20 via the host interface circuit 13, the processor 12 performs control according to the instruction. For example, the processor 12 instructs the memory interface circuit 15 to perform a write operation on the memory packages PKG0 and PKG1 in accordance with an instruction from the host computer 20. The processor 12 instructs the memory interface circuit 15 to perform a read operation on the memory packages PKG0 and PKG1 in accordance with an instruction from the host computer 20.

The ECC circuit 14 encodes the user data stored in the RAM 11 to generate a codeword. The ECC circuit 14 decodes the codeword read from the memory packages PKG0 and PKG1.

The RAM 11 temporarily stores the user data received from the host computer 20 until the user data is stored in the memory packages PKG0 and PKG1, or temporarily stores the data output from the memory packages PKG0 and PKG1 until the data is transmitted to the host computer 20. The RAM 11 includes, for example, a general-purpose memory such as a static random access memory (SRAM) or a dynamic random access memory (DRAM).

In addition, FIG. 3 shows an example in which the controller CD includes the ECC circuit 14 and the memory interface circuit 15. However, the ECC circuit 14 may be built into the memory interface circuit 15. In addition, the ECC circuit 14 may be built into the memory packages PKG0 and PKG1.

### Configuration of Memory Die MD

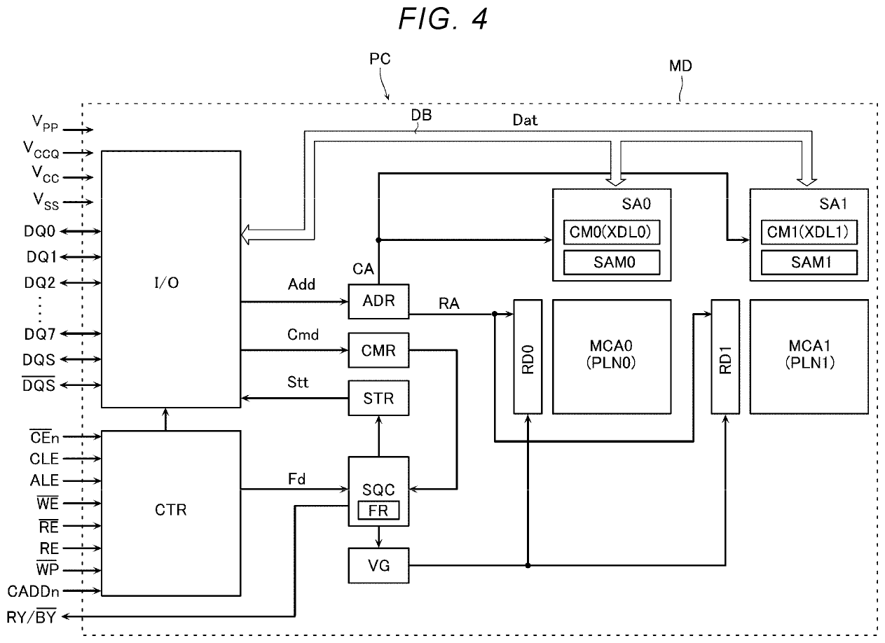

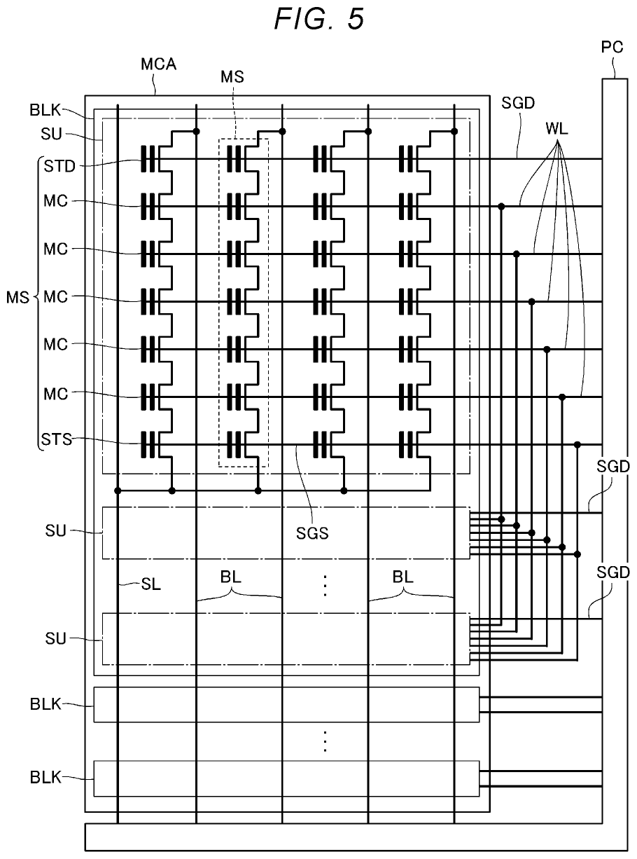

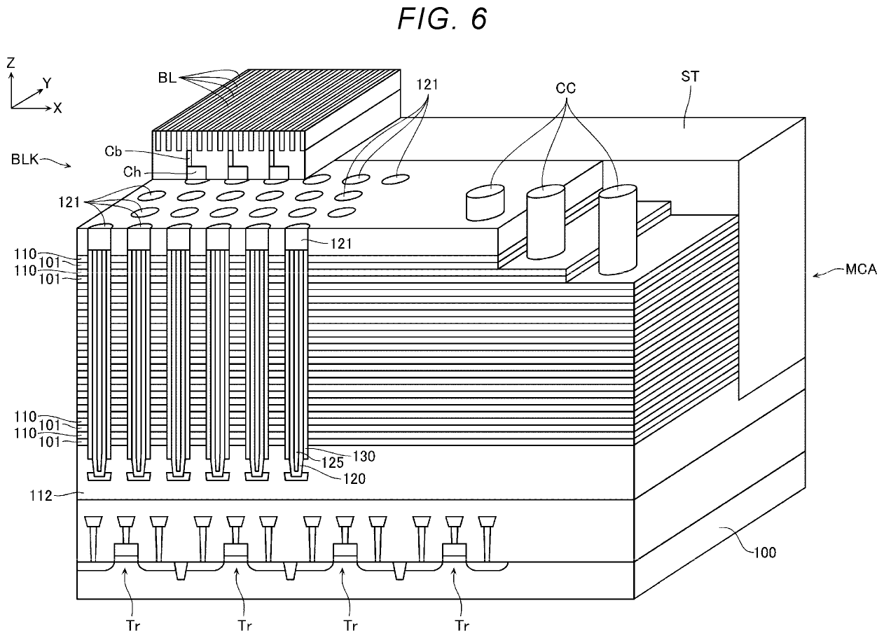

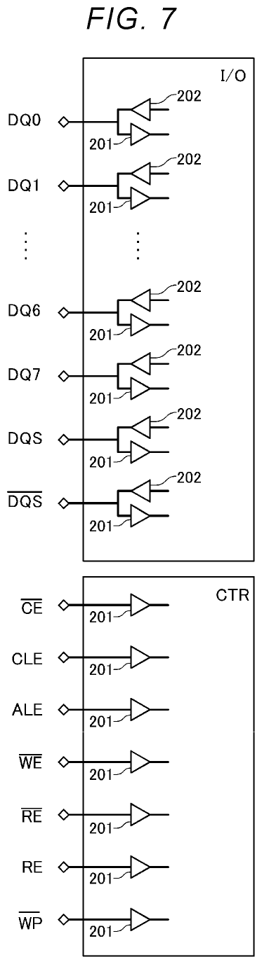

FIG. 4 is a schematic block diagram showing a configuration of the memory die MD according to the first embodiment. FIG. 5 is a schematic circuit diagram showing a configuration of a part of the memory die MD. FIG. 6 is a schematic perspective view showing a configuration of a part of the memory die MD. FIG. 7 is a schematic block diagram showing a configuration of a part of the memory die MD. For convenience of description, a part of the configuration is omitted in FIGS. 4 to 7.

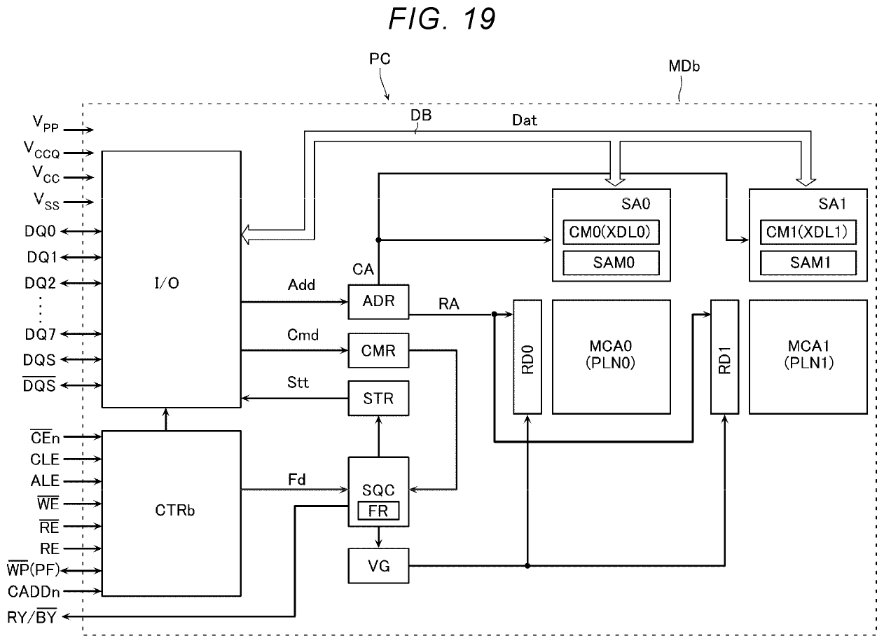

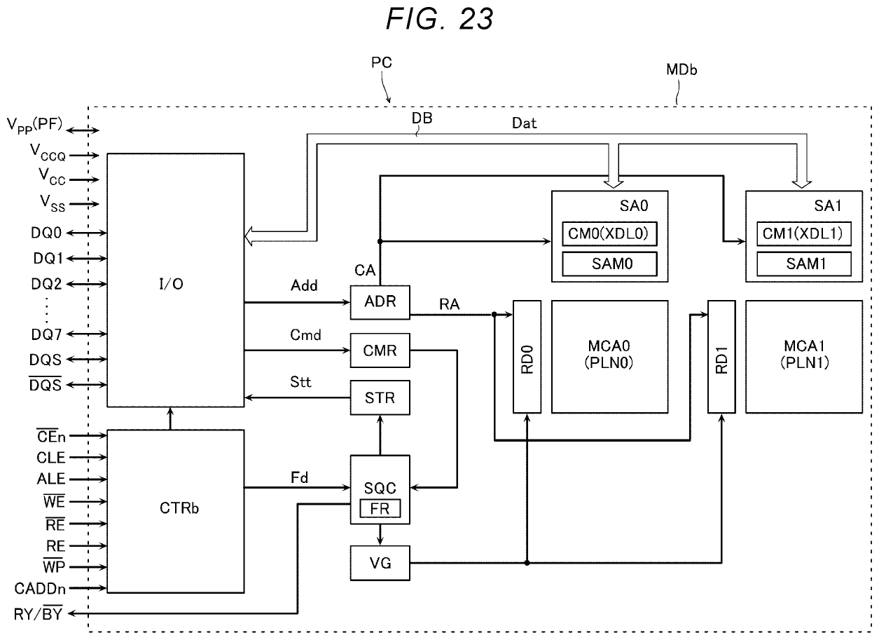

In FIG. 4, and FIGS. 19 and 23 to be described later, a plurality of control terminals and the like are shown. The plurality of control terminals may be represented as control terminals corresponding to a high active signal (a positive logic signal), may be represented as control terminals corresponding to a low active signal (a negative logic signal), and may be represented as control terminals corresponding to both the high active signal and the low active signal. In FIGS. 4, 19, and 23, the reference sign of the control terminal corresponding to the low active signal includes an overline. In the present specification, the reference sign of the control terminal corresponding to the low active signal includes a slash (“/”). The illustrations of FIGS. 4, 19, and 23 are examples, and the specific form may be adjusted as appropriate. For example, a part or all of high active signals may be set to the low active signals, or a part or all of low active signals may be set to the high active signals.

In addition, an arrow indicating the input/output direction is shown beside the plurality of control terminals shown in FIGS. 4, 19, and 23. In FIGS. 4, 19, and 23, the control terminal to which the arrow from left to right is attached can be used for inputting data or other signals from the controller CD to the memory die MD. In FIGS. 4, 19, and 23, the control terminal to which the arrow from right to left is attached can be used for outputting data or other signals from the memory die MD to the controller CD. In FIGS. 4, 19, and 23, the control terminal to which the bidirectional arrow is attached can be used for both the input of data or other signals from the controller CD to the memory die MD and the output of data or other signals from the memory die MD to the controller CD.

As shown in FIG. 4, the memory die MD includes memory cell arrays MCA0 and MCA1 that store the user data, and a peripheral circuit PC that is connected to the memory cell arrays MCA0 and MCA1. In the following description, the memory cell arrays MCA0 and MCA1 may be collectively referred to as a memory cell array MCA. In addition, the memory cell arrays MCA0 and MCA1 may be referred to as planes PLN0 and PLN1.

### Configuration of Memory Cell Array MCA

As shown in FIG. 5, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes, for example, a drain side select transistor STD between the bit line BL and the source line SL, a plurality of memory cells MC (which are memory cell transistors), and a source side select transistor STS. Hereinafter, the drain side select transistor STD and the source side select transistor STS may be simply referred to as select transistors (STD, STS).

The memory cell MC is an electric field effect type transistor that includes a semiconductor layer, a gate insulating film, and a gate electrode. The semiconductor layer functions as a channel region. The gate insulating film includes a charge storage film. A threshold voltage of the memory cell MC is changed according to a charge quantity in the charge storage film. The memory cell MC stores the user data of one bit or a plurality of bits. The word line WL is connected to each of the gate electrodes of the plurality of memory cells MC corresponding to one memory string MS. Each of these word lines WL is commonly connected to all the memory strings MS in one memory block BLK.

The select transistors (STD, STS) are electric field effect type transistors including a semiconductor layer, a gate insulating film, and a gate electrode. The semiconductor layer functions as a channel region. The select gate lines (SGD, SGS) are connected to each of the gate electrodes of the select transistors (STD, STS). The drain side select gate line SGD is provided corresponding to the string unit SU and commonly connected to all the memory strings MS in one string unit SU. The source side select gate line SGS is commonly connected to all the memory strings MS in the memory block BLK.

The memory cell array MCA is provided above the semiconductor substrate 100, for example, as shown in FIG. 6. In the example of FIG. 6, a plurality of transistors Tr of the peripheral circuit PC are provided between the semiconductor substrate 100 and the memory cell array MCA.

The memory cell array MCA includes a plurality of memory blocks BLK arranged in the Y direction. An inter-block insulating layer ST made of silicon oxide (SiO₂) or the like is provided between two memory blocks BLK adjacent to each other in the Y direction.

For example, as shown in FIG. 6, the memory block BLK includes a plurality of conductive layers 110 arranged in the Z direction, a plurality of semiconductor pillars 120 extending in the Z direction, and a plurality of gate insulating films 130 respectively provided between the plurality of conductive layers 110 and the plurality of semiconductor pillars 120.

The conductive layer 110 is a substantially plate-shaped conductive layer extending in the X direction. The conductive layer 110 may include a stacked film of a barrier conductive film made of titanium nitride (TiN) or the like and a metal film made of tungsten (W) or the like. The conductive layer 110 may contain, for example, polycrystalline silicon containing impurities such as phosphorus (P) or boron (B). Insulating layers 101 made of silicon oxide (SiO₂) or the like are provided between the plurality of conductive layers 110 arranged in the Z direction.

Among the plurality of conductive layers 110, one or a plurality of conductive layers 110 located on the lowest layer function as the source side select gate line SGS (FIG. 5) and the gate electrodes of the plurality of source side select transistors STS connected to the source side select gate line SGS. The plurality of conductive layers 110 are electrically independent for each memory block BLK.

Each of the plurality of conductive layers 110 located above the above-described conductive layers 110 functions as the word line WL (FIG. 5) and the gate electrodes of the plurality of memory cells MC (FIG. 5) connected to the word line WL. The plurality of conductive layers 110 are electrically independent for each memory block BLK.

One or a plurality of conductive layers 110 located above the above-described conductive layers 110 function as the drain side select gate line SGD and the gate electrodes of the plurality of drain side select transistors STD (FIG. 5) connected to the drain side select gate line SGD. Each of the plurality of conductive layers 110 is electrically independent for each string unit SU.

A semiconductor layer 112 is provided below the conductive layer 110. The semiconductor layer 112 may contain, for example, polycrystalline silicon containing impurities such as phosphorus (P) or boron (B). The insulating layer 101 made of silicon oxide (SiO₂) or the like is provided between the semiconductor layer 112 and the conductive layer 110.

The semiconductor layer 112 functions as the source line SL (FIG. 5). The source line SL is provided in common for all the memory blocks BLK in the memory cell array MCA, for example.

For example, as shown in FIG. 6, the semiconductor pillars 120 are arranged in the X direction and the Y direction in a predetermined pattern. The semiconductor pillar 120 functions as a channel region of the plurality of memory cells MC and select transistors (STD, STS) in one memory string MS (FIG. 5). The semiconductor pillar 120 is a semiconductor layer made of polycrystalline silicon (Si) or the like, for example. For example, as shown in FIG. 6, the semiconductor pillar 120 has a substantially cylindrical shape, and an insulating layer 125 made of silicon oxide or the like is provided at the central portion of the semiconductor pillar 120. An outer peripheral surface of each of the semiconductor pillars 120 is surrounded by the conductive layer 110 and faces the conductive layer 110.

An impurity region 121 containing N-type impurities such as phosphorus (P) is provided at an upper end portion of the semiconductor pillar 120. The impurity region 121 is connected to the bit line BL via a contact Ch and a contact Cb.

The gate insulating film 130 has a substantially cylindrical shape that covers the outer peripheral surface of the semiconductor pillar 120. For example, the gate insulating film 130 includes a tunnel insulating film, a charge storage film, and a block insulating film, which are stacked between the semiconductor pillar 120 and the conductive layer 110. The tunnel insulating film and the block insulating film are insulating films made of silicon oxide (SiO₂) or the like, for example. The charge storage film is a film that is made of silicon nitride (Si₃N₄) or the like and is capable of storing charges, for example. The tunnel insulating film, the charge storage film, and the block insulating film have a substantially cylindrical shape, and extend in the Z direction along the outer peripheral surface of the semiconductor pillar 120 except for a contact portion between the semiconductor pillar 120 and the semiconductor layer 112.

The gate insulating film 130 may include, for example, a floating gate made of polycrystalline silicon or the like containing N-type or P-type impurities.

A plurality of contacts CC are provided at the end portions of the plurality of conductive layers 110 in the X direction. The plurality of conductive layers 110 are connected to the peripheral circuit PC (FIG. 4) via the plurality of contacts CC. As shown in FIG. 6, the plurality of contacts CC extend in the Z direction and are connected to the conductive layer 110 at the lower ends. The contact CC may include, for example, a stacked film of a barrier conductive film made of titanium nitride (TiN) or the like and a metal film made of tungsten (W) or the like.

### Configuration of Peripheral Circuit PC

For example, as shown in FIG. 4, the peripheral circuit PC includes row decoders RD0 and RD1 and sense amplifiers SA0 and SA1 respectively connected to the memory cell arrays MCA0 and MCA1. The peripheral circuit PC includes a voltage generation circuit VG and a sequencer SQC. The peripheral circuit PC includes an input/output control circuit I/O, a logic circuit CTR, an address register ADR, a command register CMR, and a status register STR. In the following description, the row decoders RD0 and RD1 may be referred to as a row decoder RD, and the sense amplifiers SA0 and SA1 may be referred to as a sense amplifier SA.

### Configuration of Row Decoder RD

The row decoder RD (FIG. 4) includes an address decoder that decodes address data Add (FIG. 4) and a block select circuit and a voltage select circuit that transfer operation voltage to the memory cell array MCA according to an output signal of the address decoder.

The address decoder sequentially refers to the row address RA of the address register ADR (FIG. 4) in accordance with the control signal from the sequencer SQC, decodes the row address RA, sets the predetermined block select transistor and the voltage select transistor corresponding to the row address RA to the ON state, and sets the rest of other block select transistors and the voltage select transistors to the OFF state.

### Configuration of Sense Amplifier SA

Each of the sense amplifiers SA0 and SA1 (FIG. 4) includes sense amplifier modules SAM0 and SAM1, and cache memories CM0 and CM1 (also referred to as data registers herein). Each of the cache memories CM0 and CM1 includes latch circuits XDL0 and XDL1.

In the following description, the sense amplifier modules SAM0 and SAMI may be collectively referred to as a sense amplifier module SAM, the cache memories CM0 and CM1 may be collectively referred to as a cache memory CM, and the latch circuits XDL0 and XDL1 may be referred to as a latch circuit XDL.

The sense amplifier module SAM includes, for example, sense circuits respectively corresponding to a plurality of bit lines BL (FIG. 5), and a plurality of latch circuits connected to the sense circuits. The sense circuit detects the voltage or current of the bit line BL and outputs data indicating the detection result. The latch circuit stores the data output from the sense circuit, the user data Dat input from the cache memory CM, and the like.

The cache memory CM includes a plurality of latch circuits XDL. Each of the plurality of latch circuits XDL is connected to a latch circuit in the sense amplifier module SAM. The latch circuit XDL stores, for example, user data Dat, which is written to the memory cell MC, or user data Dat, which is read from the memory cell MC.

A column decoder is connected to the cache memory CM. The column decoder decodes a column address CA (FIG. 4) that is stored in the address register ADR (FIG. 4) and selects the latch circuit XDL that corresponds to the column address CA.

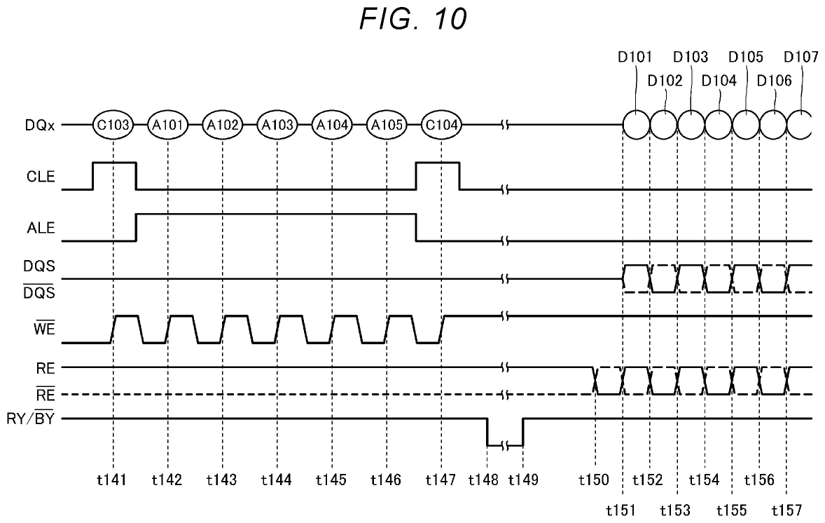

The user data Dat, which are stored in the plurality of latch circuits XDL, are sequentially transferred to the latch circuit in the sense amplifier module SAM at the time of the write operation. The user data Dat, which are provided in the latch circuit in the sense amplifier module SAM, are sequentially transferred to the latch circuit XDL at the time of the read operation. The user data Dat, which are provided in the latch circuit XDL, are sequentially transferred to the input/output control circuit I/O at the time of a data out operation, which will be described later with reference to FIG. 10 and the like.

### Configuration of Voltage Generation Circuit VG

The voltage generation circuit VG (FIG. 4) includes, for example, a step-down circuit such as a regulator and a step-up circuit such as a charge pump circuit. The step-down circuit and the step-up circuit are connected, respectively, to a power supply terminal V_{CC} and a power supply terminal V_{PP} to which a power supply voltage is supplied through a voltage supply line, and a ground terminal V_{SS} (FIG. 4) to which a ground voltage is supplied. Each of the power supply terminal V_{CC}, the power supply terminal V_{PP}, and the ground terminal V_{SS} is implemented by, for example, the pad electrode P described with reference to FIGS. 1 and 2.

For example, the voltage generation circuit VG generates a plurality of operation voltages to be applied to the bit line BL, the source line SL, the word line WL, and the select gate lines (SGD, SGS) at the time of the read operation, the write operation, and the erasing operation with respect to the memory cell array MCA according to the control signal from the sequencer SQC, and simultaneously outputs the plurality of operation voltages to the plurality of voltage supply lines. The operation voltage, which is output from the voltage supply line, is appropriately adjusted according to the control signal from the sequencer SQC.

### Configuration of Sequencer SQC

The sequencer SQC (FIG. 4) outputs an internal control signal to the row decoders RD0 and RD1, the sense amplifier modules SAM0 and SAMI, and the voltage generation circuit VG in accordance with command data Cmd stored in the command register CMR. The sequencer SQC outputs status data Stt, which indicates a state of an internal operation of the memory die MD, to the appropriate status register STR.

The sequencer SQC generates a ready/busy signal and outputs the generated ready/busy signal to a terminal RY//BY. For example, the sequencer SQC generates a true-ready/true-busy signal, a read-ready/read-busy signal, and a cache-ready/cache-busy signal as the ready/busy signal. The ready/busy signal output to the terminal RY//BY may be the true-ready/true-busy signal, the read-ready/read-busy signal, or the cache-ready/cache-busy signal. The ready/busy signal output to the terminal RY//BY may be specified by the feature data Fd. The terminal RY//BY is implemented, for example, by the pad electrode P described with reference to FIGS. 1 and 2.

In the following description, a state in which the ready/busy signal output from the terminal RY//BY is “H” and a state in which the ready/busy signal is “L” may be referred to as a ready state and a busy state, respectively. In addition, a period in which the ready/busy signal output from the terminal RY//BY is “H” and a period in which the ready/busy signal is “L” may be referred to as a ready period and a busy period, respectively.

The true-ready/true-busy signal enters an “L” state during operations that supply voltage to the memory cell array MCA, such as a read operation, a write operation, an erasing operation, and during the execution of a set feature and the like to be described later, and enters an “H” state during other times. Even when operations, such as the data out to be described later, or the status read to be described later, with reference to FIG. 10 or the like, are executed, the true-ready/true-busy signal does not enter an “L” state. In a period in which the true-ready/true-busy signal enters an “L” state (busy period), access to the memory die MD is basically prohibited. In addition, in a period in which the true-ready/true-busy signal enters an “H” state (ready period), access to the memory die MD is permitted.

In the following description, a state in which the true-ready/true-busy signal is “H” and a state in which the true-ready/true-busy signal is “L” may be referred to as a true-ready state and a true-busy state, respectively. In addition, a period in which the true-ready/true-busy signal is “H” and a period in which the true-ready/true-busy signal is “L” may be referred to as a true-ready period and a true-busy period, respectively.

The read-ready/read-busy signal enters an “H” state when a command to instruct a read operation can be received, and enters an “L” state when the command cannot be received.

In the following description, a state in which the read-ready/read-busy signal is “H” and a state in which the read-ready/read-busy signal is “L” may be referred to as a read-ready state and a read-busy state, respectively. In addition, a period in which the read-ready/read-busy signal is “H” and a period in which the read-ready/read-busy signal is “L” may be referred to as a read-ready period and a read-busy period, respectively.

The cache-ready/cache-busy signal enters an “H” state when a command to instruct a cache read described later can be received, and enters an “L” state when the command cannot be received.

In the following description, a state in which the cache-ready/cache-busy signal is “H” and a state in which the cache-ready/cache-busy signal is “L” may be referred to as a cache-ready state and a cache-busy state, respectively. In addition, a period in which the cache-ready/cache-busy signal is “H” and a period in which the cache-ready/cache-busy signal is “L” may be referred to as a cache-ready period and a cache-busy period, respectively.

The sequencer SQC includes a feature register FR (FIG. 4). The feature register FR is a register that stores the feature data Fd. The feature data Fd includes, for example, a control parameter and the like of the memory die MD. The feature data Fd is rewritable, for example, by the execution of the set feature.

### Configuration of Address Register ADR

As shown in FIG. 4, the address register ADR is connected to the input/output control circuit I/O and stores the address data Add that is input from the input/output control circuit I/O. The address register ADR includes, for example, a plurality of 8-bit register rows. When an internal operation such as a read operation, a write operation, or an erasing operation is executed, the register row stores a plurality of address data Add including address data Add corresponding to the operation being executed and address data Add corresponding to the next operation to be executed, for example.

The address data Add includes, for example, the column address CA (FIG. 4) and the row address RA (FIG. 4). The row address RA includes, for example, a block address that specifies the memory block BLK (FIG. 5), a page address that specifies the string unit SU and the word line WL, a plane address that specifies a memory cell array MCA (plane), and a chip address that specifies the memory die MD.

The chip address is defined by, for example, a chip address setting terminal CADD (FIG. 1 and FIG. 2). Hereinafter, such a chip address may be referred to as a “hard chip address”. The hard chip address is given in eight variations corresponding to the eight memory dies MD provided in each of the memory packages PKG0 and PKG1. For example, in the example of FIG. 2, “0, 0, 0”, “0, 1, 1”, “0, 0, 1”, “0, 1, 0”, “1, 0, 1”, “1, 0, 0”, “1, 1, 0”, and “1, 1, 1” are assigned to each of the memory dies MD0 to MD7 as hard chip addresses.

For example, when the 16 memory dies MD provided in the memory packages PKG0 and PKG1 are operated one by one, “L” is input to one of the external control terminals /CE0 and /CE1, “H” is input to the other, and then the hard chip address is specified. For example, when specifying the memory die MD1 (FIG. 1) in the memory package PKG0, “L” is input to the external control terminal /CE0, and “0, 1, 1” is input as the hard chip address.

### Configuration of Command Register CMR

The command register CMR is connected to the input/output control circuit I/O and stores the command data Cmd that is input from the input/output control circuit I/O. The command register CMR includes at least one set of 8-bit register rows, for example. When the command data Cmd is stored in the command register CMR, a control signal is input to the sequencer SQC. Configuration of Status Register STR

The status register STR is connected to the input/output control circuit I/O and stores the status data Stt to be output to the input/output control circuit I/O. The status register STR includes, for example, a plurality of 8-bit register rows.

The status data Stt includes, for example, information regarding ready/busy, information regarding pass/fail, and the like indicating the state of each memory die MD. The information regarding ready/busy, for example, indicates whether an internal operation such as a read operation, a write operation, or an erasing operation is being executed in each memory die MD. The information regarding pass/fail, for example, indicates whether the internal operation described above has successfully completed in each memory die MD.

The status data Stt includes, for example, 8 bits. Each bit indicates, for example, a ready state/busy state and a fail/pass by “1”/“0”, respectively.

One bit of the 8 bits of the status data Stt indicates, for example, whether the result of the verify operation, which was last executed in the most recent write operation or erasing operation corresponding to the memory cell MC storing the one-bit data, is pass or fail. One bit of the 8 bits indicates, for example, whether the result of the verify operation, which was last executed in one previous write operation or erasing operation corresponding to the memory cell MC storing one-bit data, is pass or fail. One bit of the 8 bits indicates, for example, whether the result of the verify operation, which was last executed in the most recent write operation or erasing operation corresponding to the memory cell MC storing a plurality of bits of data, is pass or fail. One bit of the 8 bits indicates, for example, whether the result of the verify operation, which was last executed in one previous write operation or erasing operation corresponding to the memory cell MC storing a plurality of bits data, is pass or fail.

In addition, one bit of the 8 bits of the status data Stt indicates, for example, whether the true-ready state or the true-busy state is in effect. One bit of the 8 bits indicates, for example, whether a read-ready state or a read-busy state is in effect. One bit of the 8 bits indicates, for example, whether a cache-ready state or a cache-busy state is in effect. One bit of the 8 bits indicates whether the write protection is valid or invalid. Such assignment to each bit of the status data Stt is merely an example, and the assignment can be appropriately adjusted.

### Configuration of Input/Output Control Circuit I/O

The input/output control circuit I/O (FIG. 4) includes data signal input/output terminals DQ0 to DQ7, data strobe signal input/output terminals DQS and /DQS, a shift register, and a buffer circuit. Each circuit in the input/output control circuit I/O (FIG. 4) is connected to the power supply terminal V_{CCQ} and the ground terminal V_{SS} to which the power supply voltage is supplied. The power supply terminal V_{CCQ} is implemented, for example, by the pad electrode P described with reference to FIGS. 1 and 2.

Each of the data signal input/output terminals DQ0 to DQ7 and the data strobe signal input/output terminals DQS and /DQS is implemented by the pad electrode P described with reference to FIGS. 1 and 2, for example. The data, which is input via the data signal input/output terminals DQ0 to DQ7, is input from the buffer circuit to the cache memory CM, the address register ADR, the command register CMR, or the feature register FR in accordance with the internal control signal from the logic circuit CTR. The data, which is output via the data signal input/output terminals DQ0 to DQ7, is input to the buffer circuit from the cache memory CM, the status register STR, or the feature register FR in accordance with the internal control signal from the logic circuit CTR. The functions and the like of the data strobe signal input/output terminal DQS and /DQS will be described later.

The input/output control circuit I/O (FIG. 4) includes, for example, an input circuit 201 and an output circuit 202 connected to each of the data signal input/output terminals DQ0 to DQ7 and the data strobe signal input/output terminals DQS and /DQS, as shown in FIG. 7. The input circuit 201 is, for example, a receiver such as a comparator. The output circuit 202 is, for example, a driver such as an off chip driver (OCD) circuit.

### Configuration of Logic Circuit CTR

The logic circuit CTR (FIG. 4 and FIG. 7) includes a plurality of external control terminals /CE, CLE, ALE, /WE, /RE, RE, and /WP and a logic circuit that is connected to the plurality of external control terminals /CE, CLE, ALE, /WE, /RE, RE, and /WP. The logic circuit CTR receives an external control signal from the controller CD via the external control terminals /CE, CLE, ALE, /WE, /RE, RE, and /WP and outputs the internal control signal to the input/output control circuit I/O in response to the external control signals.

The functions of the external control terminals /CE, CLE, ALE, /WE, /RE, RE, and /WP will be described later. The signal (for example, a write protection signal) input via the external control terminal /WP is used for restricting the input of the user data Dat from the controller CD to the memory die MD.

The logic circuit CTR includes, for example, an input circuit 201 connected to each of the external control terminals /CE, CLE, ALE, /WE, /RE, RE, and /WP as shown in FIG. 7. Each of the external control terminals /CE, CLE, ALE, /WE, /RE, RE, /WP is implemented, for example, by the pad electrode P described with reference to FIGS. 1 and 2.

### Operation

Next, the operation of the memory die MD will be described.

The memory die MD is configured to execute a read operation. The read operation is an operation of reading the user data Dat from the memory cell array MCA by the sense amplifier module SAM (FIG. 4), storing the read user data Dat in the latch circuit in the sense amplifier module SAM, and transferring the user data Dat to the latch circuit XDL (FIG. 4). In the read operation, the user data Dat read from the memory cell array MCA is transferred to the latch circuit XDL via the bit line BL and the sense amplifier module SAM.

In addition, the memory die MD is configured to execute data output as described with reference to FIG. 10 and the like. The data output is an operation of outputting the user data Dat provided in the latch circuit XDL (FIG. 4) to the controller CD (FIG. 1). In the data output, the user data Dat provided in the latch circuit XDL is output to the controller CD via the bus wiring DB and the input/output control circuit I/O.

In addition, the memory die MD is configured to execute a cache read. The cache read is basically executed in the same manner as the read operation. Meanwhile, in the cache read, the user data Dat read from the memory cell array MCA is stored in the latch circuit in the sense amplifier module SAM until otherwise instructed, and is not transferred to the latch circuit XDL (FIG. 4). Therefore, the cache read is executable even after the execution of the read operation and before the execution of the data output.

In addition, the memory die MD is configured to execute a write operation. The write operation is an operation of storing the user data Dat input from the controller CD in the latch circuit in the sense amplifier module SAM and writing the user data Dat into the memory cell MC in the memory cell array MCA. In the write operation, the program operation of storing electrons in the charge storage film of the memory cell MC and the verify operation of determining whether the threshold voltage of the memory cell MC has increased to the target value are executed once or a plurality of times.

When it is determined that the threshold voltage of the memory cell MC has increased up to the target value in the verify operation that is executed at the end of the write operation, information indicating pass is recorded in one bit of the status data Stt. On the other hand, when it is determined that the threshold voltage of the memory cell MC has not increased up to the target value in the verify operation that is executed at the end of the write operation, information indicating a fail is recorded in one bit of the status data Stt. In such a case, the controller CD determines the memory block BLK including the memory cell MC in which the write operation is executed as a defective block, for example. A write operation, an erasing operation, and the like are not executed on the memory block BLK determined as a defective block.

In addition, the memory die MD is configured to execute an erasing operation. The erasing operation is an operation of erasing data written in the memory cell MC in the memory cell array MCA. In the erasing operation, the erase voltage supply operation of removing electrons from the charge storage film of the memory cell MC and the verify operation of determining whether the threshold voltage of the memory cell MC has decreased to the target value are executed once or a plurality of times.

When it is determined that the threshold voltage of the memory cell MC has decreased to the target value in the verify operation that is executed at the end of the erasing operation, information indicating pass is recorded in one bit of the status data Stt. On the other hand, when it is determined that the threshold voltage of the memory cell MC has not decreased to the target value in the verify operation that is executed at the end of the erasing operation, information indicating fail is recorded in one bit of the status data Stt. In such a case, the controller CD determines the memory block BLK including the memory cell MC in which the erasing operation is executed as a defective block, for example. A write operation, an erasing operation, and the like are not executed on the memory block BLK determined as a defective block.

In addition, the memory die MD is configured to execute a status read (which is a status information output operation). The status read is an operation of outputting the status data Stt provided in the status register STR (FIG. 4) to the controller CD (FIG. 1) via the input/output control circuit I/O.

In addition, the memory die MD is configured to execute the set feature. The set feature is an operation of inputting the feature data Fd to the feature register FR (FIG. 4). In the set feature, the feature data Fd is input to the feature register FR from the controller CD via the input/output control circuit I/O or the logic circuit CTR.

### Role of External Control Terminal

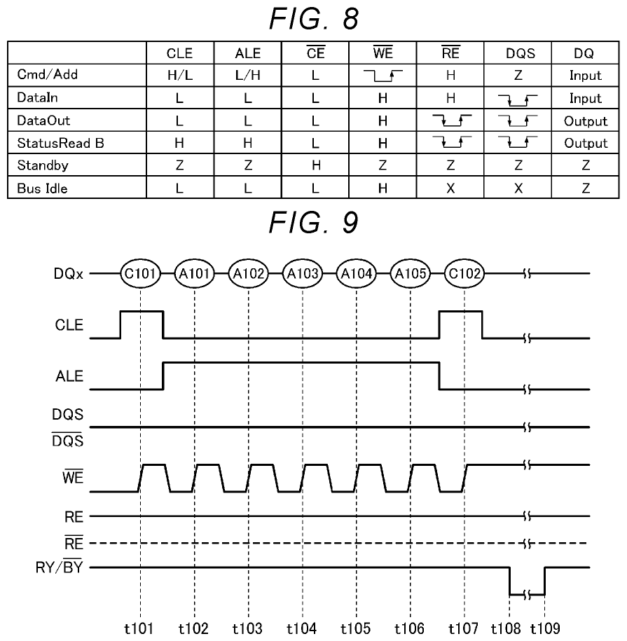

FIG. 8 is a truth table showing the roles of external control terminals of the memory die MD. In FIG. 8, “Z” indicates a case where either “H” or “L” may be input. “X” indicates a case where an input signal is fixed to “H” or “L”. “Input” indicates a case where data is input. “Output” indicates a case where data is output.

When the input and output of the signal are performed with respect to the memory die MD, “L” is input to the external control terminal /CE.

When the command data Cmd is input, the controller CD raises the voltage of the external control terminal /WE from “L” to “H” in a state where the voltages of the data signal input/output terminals DQ0 to DQ7 are set to “H” or “L” in accordance with each bit of the 8-bit command data Cmd, “H” is input to the external control terminal CLE, and “L” is input to the external control terminal ALE.

When “H, L” are input to the external control terminals CLE and ALE, the data input via the data signal input/output terminals DQ0 to DQ7 is stored in the buffer memory in the input/output control circuit I/O as the command data Cmd and is transferred to the command register CMR (FIG. 4).

In addition, when the address data Add is input, the controller CD raises the voltage of the external control terminal /WE from “L” to “H” in a state where the voltages of the data signal input/output terminals DQ0 to DQ7 are set to “H” or “L” in accordance with each bit of 8-bit data that make up the address data Add, “L” is input to the external control terminal CLE, and “H” is input to the external control terminal ALE.

When “L, H” are input to the external control terminals CLE and ALE, the data input via the data signal input/output terminals DQ0 to DQ7 is stored in the buffer memory in the input/output control circuit I/O as the address data Add and is transferred to the address register ADR (FIG. 4).

In case of the data input that inputs the user data Dat, the controller CD toggles the input signals of the data strobe signal input/output terminals DQS and /DQS in a state where the voltages of the data signal input/output terminals DQ0 to DQ7 are set to “H” or “L” in accordance with each bit of 8-bit data that make up the user data Dat, “L” is input to the external control terminal CLE, and “L” is input to the external control terminal ALE.

When “L” is input to both the external control terminals CLE and ALE, the data input via the data signal input/output terminals DQ0 to DQ7 is stored in the buffer memory in the input/output control circuit I/O as the user data Dat and is transferred to the cache memory CM (FIG. 4) via the bus DB.

In case of the data output that outputs the user data Dat, the controller CD toggles the input signals of the external control terminals /RE and RE, for example. Along with this, 8 bits of the output user data Dat are output to the data signal input/output terminals DQ0 to DQ7. In addition, the output signals of the data strobe signal input/output terminals DQS and /DQS toggle.

The data output mentioned here means that 8-bit data is output by toggling the input signals of the external control terminals /RE and RE once. On the other hand, the data output described later with reference to the above-described data output and FIG. 10 means an operation of transferring the user data Dat stored in the cache memory CM to the input/output control circuit I/O and further toggling the input signals of the external control terminals /RE and RE a plurality of times to output the data to the controller CD.

In case of the status read B described later, the controller CD inputs “H” to the external control terminal CLE and inputs “H” to the external control terminal ALE, for example. Along with this, 8 bits of the status data Stt are output to the data signal input/output terminals DQ0 to DQ7. In addition, the output signals of the data strobe signal input/output terminals DQS and /DQS toggle. When the 8 bits of the status data Stt are output in the status read B, the controller CD may or may not toggle the input signals of the external control terminals /RE and RE.

In addition, when setting the memory die MD to standby state, the controller CD inputs “H” to the external control terminal /CE, for example.

In addition, when setting the memory die MD to bus idle state, the controller CD inputs “H” to the external control terminal /WE, for example.

### Read Operation

Next, the role of the external control terminal when the read operation is executed will be more specifically described. FIG. 9 is a schematic waveform diagram showing the read operation of the memory die MD.

At the timings t101 to t107, the controller CD sequentially inputs the command data C101, the data A101 to A105 that make up the address data Add (FIG. 4), and the command data C102 to the memory die MD via the data signal input/output terminals DQ0 to DQ7. The command data C101 is command data Cmd that is input at the beginning of a command set that instructs the read operation. The command data C102 is command data Cmd that is input at the end of the command set that instructs the read operation. In the example of FIG. 9, the command set that instructs the read operation includes the 8-bit×5-cycle data A101 to A105 that make up the address data Add, but the number of cycles may be less than or more than 5.

At the timing t107, the command data C102 is received in response to the rising edge of the signal input to the external control terminal /WE. Accordingly, at the timing t108, the read operation is started, and the voltage of the terminal RY//BY falls from “H” to “L”.

At the timings t108 and t109, the read operation is executed, and the user data Dat read from the memory cell array MCA (FIG. 4) is transferred to the latch circuit XDL.

At the timing t109, the voltage of the terminal RY//BY rises from “L” to “H” at the timing when the read operation is completed.

### Data Output

Next, the role of the external control terminal when the data output is executed will be more specifically described. FIG. 10 is a schematic waveform diagram showing the data output of the memory die MD.

At the timings t141 to t147, the controller CD sequentially inputs the command data C103, the data A101 to A105 that make up the address data Add (FIG. 4), and the command data C104 to the memory die MD via the data signal input/output terminals DQ0 to DQ7. The command data C103 is command data Cmd that is input at the beginning of a command set that instructs the data output. The command data C104 is command data Cmd that is input at the end of the command set that instructs the data output. In the example of FIG. 10, the command set that instructs the data output includes the 8-bit×5-cycle data A101 to A105 that make up the address data Add, but the number of cycles may be less than or more than 5.

At the timing t147, the command data C104 is received in response to the rising edge of the signal input to the external control terminal /WE. Accordingly, at the timing t148, the data output is started, and the voltage of the terminal RY//BY falls from “H” to “L”.

At the timings t148 and t149, the data output is executed, and the user data Dat stored in the latch circuit XDL is transferred to the input/output circuit I/O.

At the timing t149, the voltage of the terminal RY//BY rises from “L” to “H” at the timing when the user data Dat stored in the latch circuit XDL is transferred to the input/output circuit I/O.

At the timing t150 (FIG. 10), the controller CD toggles the input signals of the external control terminals /RE and RE. Accordingly, the data output is started from the timing t151 (FIG. 10), and the user data Dat is output via the data signal input/output terminal DQ.

### Write Operation

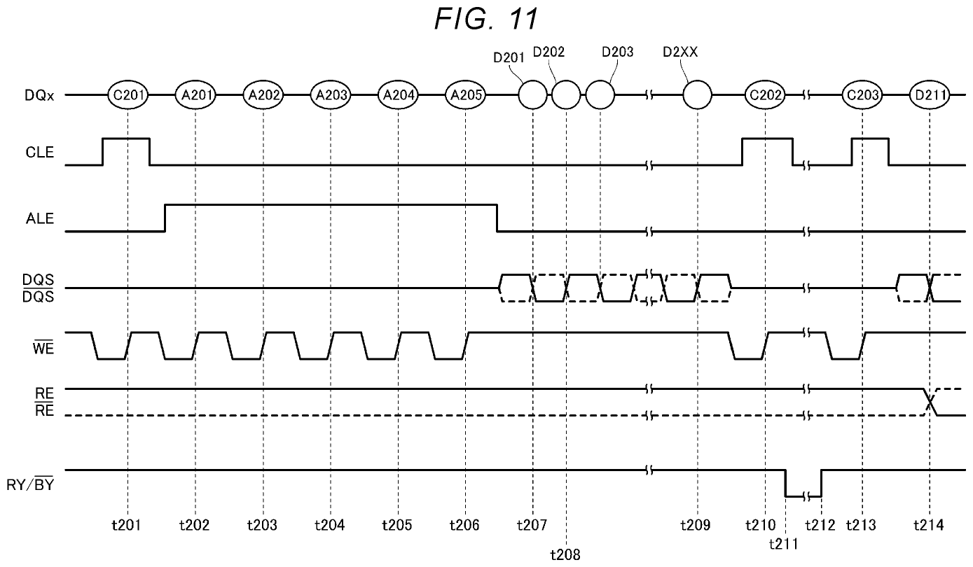

Next, the role of the external control terminal when the write operation is executed will be more specifically described. FIG. 11 is a schematic waveform diagram showing the write operation of the memory die MD.

At the timings t201 to t210, the controller CD sequentially inputs the command data C201, the data A201 to A205 that make up the address data Add (FIG. 4), the data D201 to D2XX that make up the user data Dat, and the command data C202 to the memory die MD via the data signal input/output terminals DQ0 to DQ7. The command data C201 is command data Cmd input at the beginning of a command set that instructs the write operation. The command data C202 is command data Cmd input at the end of the command set that instructs the write operation. In the example of FIG. 11, the command set that instructs the write operation includes the 8-bit×5-cycle data A201 to A205 that make up the address data Add, but the number of cycles may be less than or more than 5.

At the timing t210, the command data C202 is received in response to the rising edge of the signal input to the external control terminal /WE. Accordingly, at the timing t211, the write operation is started, and the voltage of the terminal RY//BY falls from “H” to “L”.

At the timings t211 and t212, the write operation is executed, and the user data Dat stored in the latch circuit XDL is written into the memory cell array MCA.

At the timing t212, the voltage of the terminal RY//BY rises from “L” to “H” at the timing when the write operation is completed.

At the timing t213, the controller CD inputs the command data C203 to the memory die MD via the data signal input/output terminals DQ0 to DQ7. The command data C203 is a command set that instructs the status read.

At the timing t214, the controller CD toggles the input signals of the external control terminals /RE and RE. Accordingly, the data D211 is output via the data signal input/output terminal DQ. The data D211 is status data Stt.

### Status Read A

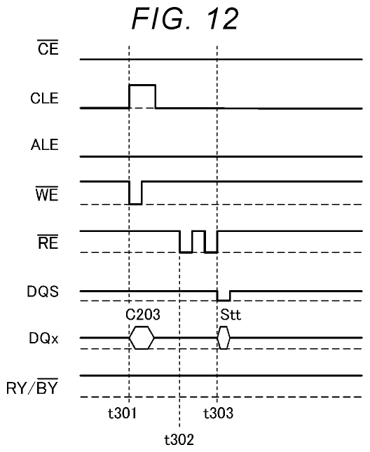

Next, the role of the external control terminal when the status read is executed will be more specifically described. FIG. 12 is a schematic waveform diagram showing the status read.

At the timing t301 (FIG. 12), the controller CD inputs the command data C203 to the memory die MD.

The controller CD toggles the input signals of the external control terminals /RE and RE at the timing t302 (FIG. 12), which is a predetermined standby time after the command data C203 is input.

At the timing t303 (FIG. 12), the memory die MD outputs 8 bits that make up the status data Stt to the data signal input/output terminals DQ0 to DQ7. In addition, the output signals of the data strobe signal input/output terminals DQS and /DQS toggles. The status data Stt corresponds to the memory die MD having the chip address specified in the immediately preceding command.

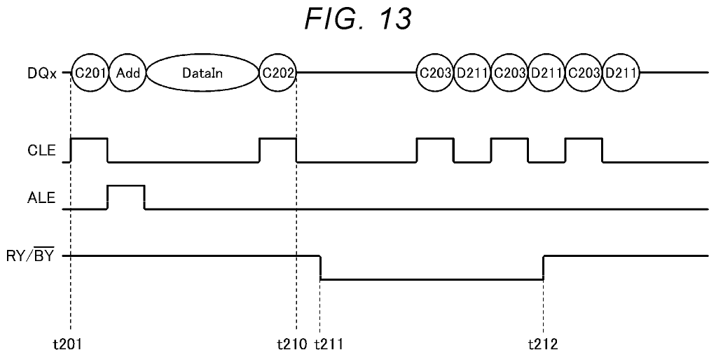

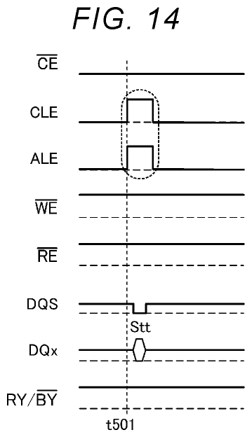

FIG. 13 is a schematic waveform diagram showing the operation of the memory die MD.

During the execution of the write operation, the status read may be repeatedly executed to monitor the status data Stt. Here, as shown in FIG. 13, since the command data C203 is input via the data signal input/output terminals DQ0 to DQ7 and the data D211 is output via the data signal input/output terminals DQ0 to DQ7, when the status read is frequently executed, the data signal input/output terminals DQ0 to DQ7 may be occupied. When the occupancy of the data signal input/output terminals DQ0 to DQ7 is reduced, it may be possible to achieve the acceleration of the operation.

Therefore, the memory system 10 according to the first embodiment is configured to execute an operation of outputting the status data Stt without inputting the command data C203. In the present specification, the status read described with reference to FIG. 12 or the like may be referred to as a “status read A” for the sake of distinction. In addition, the operation of outputting the status data Stt without inputting the command data C203 may be referred to as a “status read B”.

### Status Read B

Next, the role of the external control terminal when the status read B is executed will be more specifically described. FIG. 14 is a schematic waveform diagram showing the status read B.

At the timing t501, the controller CD inputs “H” to the external control terminal CLE and the external control terminal ALE, and the status read B is instructed at the timing of the rising edge of the external control terminal CLE and the external control terminal ALE.

When “H” is input to the external control terminal CLE and the external control terminal ALE, 8 bits of the status data Stt are output via the data signal input/output terminals DQ0 to DQ7. In addition, the output signals of the data strobe signal input/output terminals DQS and /DQS toggle. The status data Stt corresponds to the memory die MD having the chip address specified in the immediately preceding command.

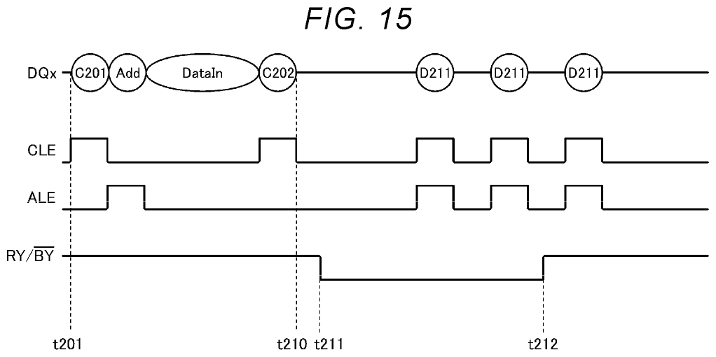

FIG. 15 is a schematic waveform diagram showing the operation of the memory die MD.

As shown in FIG. 15, in the status read B, it is not necessary to input the command data C203, and the status data Stt can be output by inputting “H” to the external control terminal CLE and the external control terminal ALE. Therefore, even when the status data Stt is frequently output, it is possible to reduce the occupancy rate of the data signal input/output terminals DQ0 to DQ7 to achieve the acceleration of the operation.

### Modification Example 1 of First Embodiment

In the memory system 10 according to the first embodiment (FIG. 1), when the status data Stt is output by the status read B, the status data Stt for the memory die MD having the chip address specified in the immediately preceding command is output.

However, such a method is merely an example, and the method of specifying the memory die MD that is the target of the status read B can be appropriately adjusted. Hereinafter, as Modification Example 1 of the first embodiment, a method of specifying the memory die MD to be the target of the status read B using the chip address setting terminal CADD will be described.

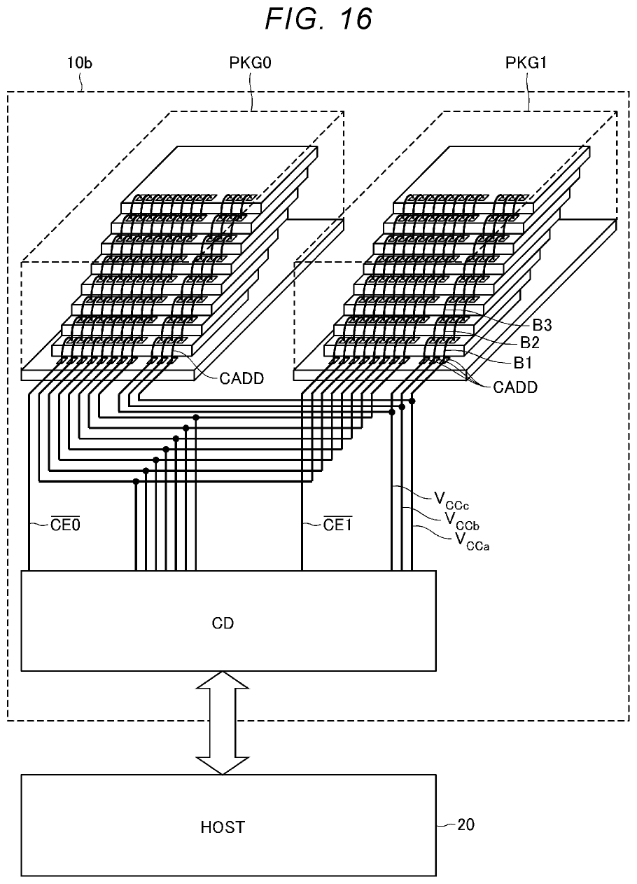

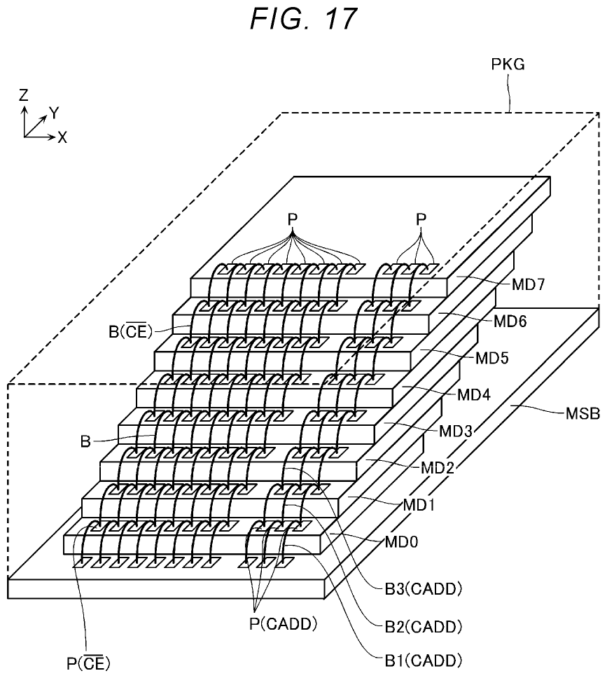

FIG. 16 is a schematic block diagram showing Modification Example 1 of the first embodiment. FIG. 17 is a schematic perspective view showing the present modification Example.

A memory system 10b (FIG. 16) according to the present modification example is basically configured in the same manner as the memory system 10 of FIG. 1. However, in the memory system 10b (FIG. 16), among the plurality of pad electrodes P provided in the plurality of memory dies MD0 to MD7, the pad electrodes P functioning as the chip address setting terminal CADD are connected to the bonding wires B1 to B3 as follows.

For example, in the example of FIG. 17, the first bonding wire B1 is commonly connected to the first chip address setting terminal CADD (pad electrode P) from the positive side in the X direction of the memory dies MD0 to MD7. In addition, the second bonding wire B2 is commonly connected to the second chip address setting terminal CADD (pad electrode P) from the positive side in the X direction of the memory dies MD0 to MD7. In addition, the third bonding wire B3 is commonly connected to the third chip address setting terminal CADD (pad electrode P) from the positive side in the X direction of the memory dies MD0 to MD7.

As shown in FIG. 16, the bonding wire B1, the bonding wire B2, and the bonding wire B3 are each connected to the voltage supply line V_{CCa}, the voltage supply line V_{CCb}, and the voltage supply line V_{CCc}. The voltage supply line V_{CCa}, the voltage supply line V_{CCb}, and the voltage supply line V_{CCc} are connected to the controller CD.

The voltage supply line V_{CCa}, the voltage supply line V_{CCb}, and the voltage supply line V_{CCc} are each supplied with the voltage V_{H} or the voltage V_{L} for specifying the chip. For example, in the example of FIG. 17, eight variations of voltages “V_{L}, V_{L}, V_{L}”, “V_{L}, V_{H}, V_{H}”, “V_{L}, V_{L}, V_{H}”, “V_{L}, V_{H}, V_{L}”, “V_{H}, V_{L}, V_{H}”, “V_{H}, V_{L}, V_{L}”, “V_{H}, V_{H}, V_{L}”, and “V_{H}, V_{H}, V_{H}” are supplied to the three chip address setting terminals CADD provided in each of the memory dies MD0 to MD7 via the bonding wires B1 to B3. The voltage V_{H} is higher than the voltage V_{L}. In addition, the voltage V_{L} may be a ground voltage. By the above-described eight variations of voltages, one of the corresponding memory dies MD can be specified from the eight memory dies MD0 to MD7.

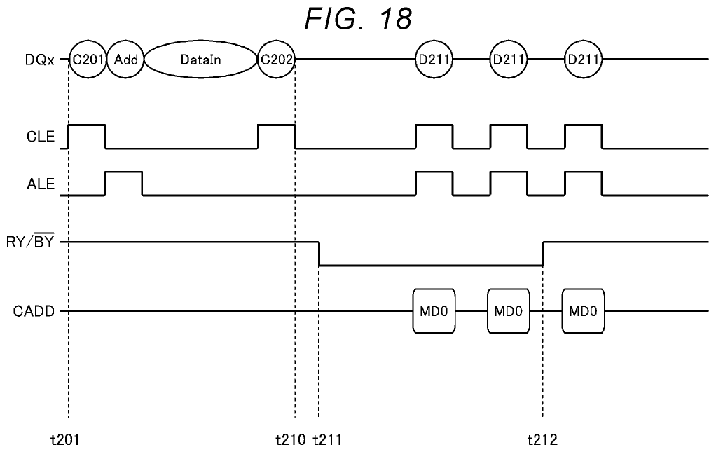

FIG. 18 is a schematic waveform diagram showing the operation of the memory die MD. In the following description with reference to FIG. 18, an operation for the memory die MD0 is described, but a plurality of memory dies MD to be the target may be any of the memory dies MD0 to MD7.

In the example of FIG. 18, during and after the execution of the write operation, the controller CD supplies the voltage specifying the memory die MD0 to the chip address setting terminal CADD, inputs “H” to the external control terminal CLE and the external control terminal ALE, and instructs the status read B. Along with this, the data D211, which is the status data Stt, is output via the data signal input/output terminals DQ0 to DQ7 at substantially the same time as the timing of the rising edges of the external control terminal CLE and the external control terminal ALE. The status data Stt includes status information of the memory die MD0 specified by the chip address setting terminal CADD.

In the example shown in FIG. 18, using the status data Stt, it is possible to confirm whether the write operation of the memory die MD0 has completed, whether the write operation has successfully completed, and the like, for example.

### Modification Example 2 of First Embodiment

In Modification Example 2 of the first embodiment, another method of specifying the memory die MD to be the target of the status read B will be described.

In the present modification example, first, the controller CD stores information indicating whether each memory die MD is an output target of the status read B in the feature register FR (FIG. 4) of each memory die MD.

In such a state, when the controller CD inputs “H” to the external control terminal CLE and the external control terminal ALE, instructing the status read B, the status data Stt can be output from one or a plurality of memory dies MD where information indicating them as the output target for the status read B is stored, in the feature register FR (FIG. 4).

### Second Embodiment

In the first embodiment, an example was provided in which the use of the status read B makes it possible to reduce the occupancy of the data signal input/output terminals DQ0 to DQ7 as compared with the status read A and to output the status data Stt at a higher speed.

However, such a method is merely an example, and another method may be used as a method for reducing the occupancy of the data signal input/output terminals DQ0 to DQ7. For example, in order to acquire the status information of each memory die MD, the information regarding ready/busy may be output by the terminal RY//BY, and the information regarding pass/fail may be output by any of the plurality of external control terminals (for example, external control terminal WP), instead of outputting the status data Stt by the status reads A and B. The internal operation information of each memory die MD can be obtained without executing the status read.

Hereinafter, such an example will be described as a second embodiment.

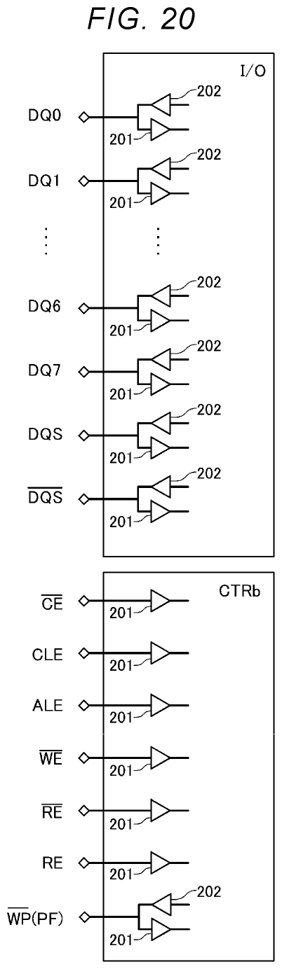

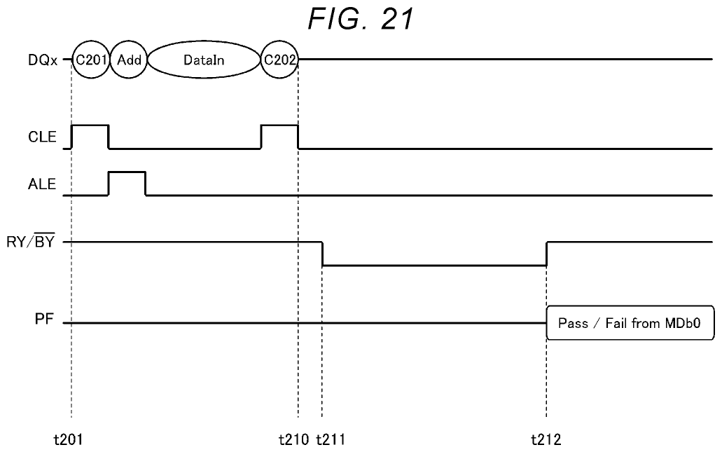

FIG. 19 is a schematic block diagram showing a second embodiment. FIG. 20 is a schematic block diagram showing the second embodiment. FIG. 21 is a waveform diagram showing the second embodiment.

The memory die MDb (FIG. 19) according to the present embodiment is basically configured in the same manner as the memory die MD of FIG. 4. However, in the memory die MDb (FIG. 19), information regarding pass/fail can be output from the external control terminal /WP. Hereinafter, when the external control terminal /WP can output information regarding pass/fail, the external control terminal /WP may be referred to as a terminal /WP (PF).

The logic circuit CTRb (FIG. 20) according to the present embodiment is basically configured in the same manner as the logic circuit CTR of FIG. 7. However, the logic circuit CTRb (FIG. 20) includes an input circuit 201 and an output circuit 202 connected to the terminal /WP (PF).

FIG. 21 shows the output of information regarding ready/busy from the terminal RY//BY and the output of information regarding pass/fail from the terminal /WP (PF) when a write operation is performed on the memory dies MDb0 according to the present embodiment. In the following description with reference to FIG. 21, an operation for the target memory die MDb0 is described, but the target memory die MDb may be any of the memory dies MDb0 to MDb7.

In the example in FIG. 21, at the timing t212 when the write operation ends, information regarding pass/fail indicating whether the write operation to the memory die MDb0 is successfully completed is output from the terminal /WP (PF). The information regarding pass/fail indicates the internal operation of the memory die MDb0 to which the write operation is instructed at the most recent timing t201 to the timing t210.

Even while the information regarding ready/busy is output from the terminal RY//BY and the information regarding pass/fail is output from the terminal /WP (PF), it is possible to input and output the command data, the address data, the user data, and the like via the data signal input/output terminals DQ0 to DQ7.

As the information regarding pass/fail output from the terminal /WP (PF), as the output signal, for example, a “H” voltage may be output when the write operation has successfully completed, and a “L” voltage may be output when the write operation has not successfully completed. Alternatively, a “L” voltage may be output when the write operation has successfully completed, and a “H” voltage may be output when the write operation has not successfully completed.

In the description above, an example was provided in which the information output from the terminal /WP (PF) is the information regarding pass/fail. Alternatively, the information output to the terminal /WP (PF) may be the information corresponding to the memory cell MC storing the data of one bit, or may be the information corresponding to the memory cell MC storing the data of a plurality of bits. In addition, the information output to the terminal /WP (PF) may be the information corresponding to the most recent write operation or erasing operation, or may be the information corresponding to one previous write operation or erasing operation. The information output to the terminal /WP (PF) may be specified by the feature data Fd. In addition, the information output from the terminal /WP (PF) may be, for example, other information that make up the status data Stt. In addition, the information output from the terminal /WP (PF) may be specified by the set feature.

### Modification Example 1 of Second Embodiment

In the memory die MDb (FIG. 19) according to the second embodiment, the information (information regarding ready/busy and pass/fail) output from the terminal RY//BY and the terminal /WP (PF) corresponds to the memory die MDb having the chip address specified in the immediately preceding command set.

However, such a method is merely an example, and the method of specifying the memory die MDb that outputs information regarding ready/busy and pass/fail can be appropriately adjusted. Hereinafter, as Modification Example 1 of the second embodiment, a method of specifying the memory die MDb that outputs information regarding ready/busy and pass/fail using the chip address setting terminal CADD will be described.

The memory system according to Modification Example 1 of the second embodiment is configured in the same manner as the memory system 10b of FIGS. 16 and 17. Therefore, any of the eight memory dies MDb0 to MDb7 can be specified by eight variations for voltages supplied to the chip address setting terminal CADD.

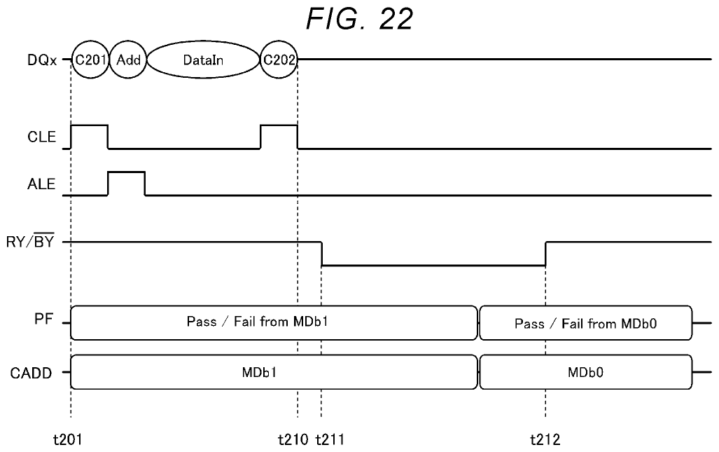

FIG. 22 is a waveform diagram showing Modification Example 1 of the second embodiment. In the following description with reference to FIG. 22, an operation for the memory dies MDb0 and MDI is described, but a plurality of memory dies MDb to be the target may be any of the memory dies MDb0 to MDb7.

In the example in FIG. 22, at the timing during the execution of the write operation, the controller CD switches the signal input to the chip address setting terminal CADD from the signal specifying the memory die MDb1 to the signal specifying the memory die MDb0. Accordingly, the information output from the terminal RY//BY is switched from the information regarding the ready/busy of the memory die MDb1 to the information regarding the ready/busy of the memory die MDb0. Further, the information output from the terminal /WP (PF) is switched from the information regarding the internal operation of the memory die MDb1 to the information regarding the internal operation of the memory die MDb0.

Even while the information regarding ready/busy is output from the terminal RY//BY and the information regarding pass/fail is output from the terminal /WP (PF), it is possible to input and output the command data, the address data, the user data, and the like via the data signal input/output terminals DQ0 to DQ7.

### Modification Example 2 of Second Embodiment

In Modification Example 2 of the second embodiment, another method will be described in which the memory die MD that outputs information regarding ready/busy and pass/fail is specified.

In the present modification example, first, the controller CD stores information indicating whether each memory die MDb is an output target of information regarding ready/busy and pass/fail in the feature register FR of each memory die MDb (FIG. 19).

In such a state, information regarding ready/busy and pass/fail is output from one memory die MDb where information indicating it as the output target for information regarding ready/busy and pass/fail is stored, via the terminal RY//BY and the terminal /WP (PF), in the feature register FR (FIG. 19).

### Other Embodiments

Hitherto, the semiconductor storage device according to the first and second embodiments has been described. However, the above description is merely an example, and specific configurations, operations, and the like can be appropriately adjusted.

For example, the memory die MDb according to the second embodiment uses the terminal /WP (PF) (FIG. 19) as a terminal that outputs information regarding pass/fail. However, such a method is merely an example, and a specific method can be appropriately adjusted.

FIG. 23 is a schematic block diagram showing another example of the second embodiment. For example, as shown in FIG. 23, the power supply terminal V_{PP} may be used as the terminal that outputs the information regarding the pass/fail. When the power supply terminal V_{PP} functions as an input/output terminal, the power supply terminal V_{PP} may be referred to as a terminal V_{PP} (PF). The power supply voltage is supplied via the terminal V_{PP} (PF) in the same manner as in the first embodiment, for example. On the other hand, the signal output via the terminal V_{PP} (PF) includes, for example, information regarding pass/fail indicating whether the internal operation of each memory die MDb is successfully completed. In such a case, the logic circuit CTRb (FIG. 23) includes an input circuit 201 and an output circuit 202 connected to the terminal V_{PP} (PF).

In addition, for example, in the first embodiment and the second embodiment, the memory system 10 (FIG. 1) and the memory system 10b (FIG. 16) each include a plurality of memory packages PKG, and the memory package PKG includes a plurality of memory dies MD0 to MD7. However, such configurations are merely examples, and the specific configuration can be appropriately adjusted. For example, the memory system 10 (FIG. 1) and the memory system 10b (FIG. 16) may each include one memory package PKG, and the memory package PKG may include one memory die MD.

In addition, for example, in the first embodiment and the second embodiment, the assignment of the function to the external control terminals CLE, ALE, /CE, and the like was described as an example. However, such an assignment is merely an example, and the assignment can be appropriately adjusted.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising a memory chip that includes:
a first control signal pad to which a first control signal is to be input;
a second control signal pad to which a second control signal is to be input;
a data signal pad to and from which a data signal is to be input and output;
a memory cell array including a plurality of memory cell transistors; and
a control circuit configured to control the memory chip based on the first and second control signals, wherein the control circuit
stores data in the data signal received through the data signal pad in a data register, when the first control signal is at a first state and the second control signal is at the first state,
stores data in the data signal received through the data signal pad in a command register, when the first control signal is at a second state and the second control signal is at the first state,
stores data in the data signal received through the data signal pad in an address register, when the first control signal is at the first state and the second control signal is at the second state, and
outputs status data when the first control signal is at the second state and the second control signal is at the second state.

2. The semiconductor storage device according to claim 1, wherein the status data output through the data signal is stored in a status data register.

3. The semiconductor storage device according to claim 1, wherein the status data includes:
information indicating whether the memory chip is in a ready state or a busy state; and
information including whether an internal operation of the memory chip has successfully completed.

4. The semiconductor storage device according to claim 3, wherein the internal operation includes a write operation and an erasing operation performed on the memory cell transistors.

5. The semiconductor storage device according to claim 1, wherein the control circuit is configured to include the status data in the data signal that is transmitted through the data signal pad.

6. The semiconductor storage device according to claim 1, wherein
the memory chip is one of a plurality of memory chips that are provided in the semiconductor storage device, and each of the other memory chips includes:
a first control signal pad to which the first control signal is to be input;
a second control signal pad to which the second control signal is to be input;
a data signal pad to and from which the data signal is to be input and output;
a memory cell array including a plurality of memory cell transistors; and
a control circuit configured to control the memory chip based on the first and second control signals, wherein the control circuit
stores data in the data signal received through the data signal pad in a data register, when the first control signal is at a first state and the second control signal is at the first state,
stores data in the data signal received through the data signal pad in a command register, when the first control signal is at a second state and the second control signal is at the first state,
stores data in the data signal received through the data signal pad in an address register, when the first control signal is at the first state and the second control signal is at the second state, and
outputs status data when the first control signal is at the second state and the second control signal is at the second state.

7. The semiconductor storage device according to claim 6, wherein
when the first control signal is at the second state and the second control signal is at the second state, one of the plurality of memory chips, which last executed an internal operation outputs the status data.

8. The semiconductor storage device according to claim 7, wherein the internal operation includes a write operation and an erasing operation performed on the memory cell transistors.

9. The semiconductor storage device according to claim 6, wherein
each of the plurality of memory chips includes one or a plurality of chip select signal pads where a chip select signal that is used for selecting one of the plurality of memory chips, is to be input, and
when the first control signal is at the second state and the second control signal is at the second state, one of the plurality of memory chips corresponding to the chip select signal outputs the status data.

10. The semiconductor storage device according to claim 6, wherein
each of the plurality of memory chips has a feature register in which chip select data that indicates a selected state or a non-selected state, is to be stored, and
when the first control signal is at the second state and the second control signal is at the second state, one of the plurality of memory chips, in which the chip select data indicates the selected state, outputs the status data.

11. A semiconductor storage device comprising a memory chip that includes:
a data signal pad to and from which a data signal is to be input and output;
a first status signal pad to which a first status signal is to be output;
a second status signal pad to which a second status signal is to be output;
a memory cell array including a plurality of memory cell transistors; and
a control circuit configured to control the memory chip, wherein the control circuit is configured to:
set the first status signal to indicate whether the memory chip is in a ready state or a busy state, and
set the second status signal to indicate whether an internal operation of the memory chip has successfully completed.

12. The semiconductor storage device according to claim 11, wherein the internal operation includes a write operation and an erasing operation performed on the memory cell transistors.

13. The semiconductor storage device according to claim 11, wherein the memory chip is configured to input and output user data through the data signal pad in a state where the first status signal is output from the first status signal pad and the second status signal is output from the second status signal pad.

14. The semiconductor storage device according to claim 11, wherein the memory chip further includes:
an input circuit connected to one of the first status signal pad and the second status signal pad to input data; and
an output circuit connected to the one of the first status signal pad and the second status signal pad to output data.

15. The semiconductor storage device according to claim 11, wherein
the memory chip is one of a plurality of memory chips that are provided in the semiconductor storage device, and each of the other memory chips includes:
a data signal pad to and from which the data signal is to be input and output;
a first status signal pad to which a first status signal is to be output;
a second status signal pad to which a second status signal is to be output;
a memory cell array including a plurality of memory cell transistors; and
a control circuit configured to control the memory chip, wherein the control circuit is configured to:
set the first status signal to indicate whether the memory chip is in a ready state or a busy state, and
set the second status signal to indicate whether an internal operation of the memory chip has successfully completed.

16. The semiconductor storage device according to claim 15, wherein
the first status signal and the second status signal are output from one of the plurality of memory chips, which last executed an internal operation.

17. The semiconductor storage device according to claim 16, wherein the internal operation includes a write operation and an erasing operation performed on the memory cell transistors.

18. The semiconductor storage device according to claim 15, wherein
each of the plurality of memory chips includes one or a plurality of chip select signal pads where a chip select signal that is used for selecting one of the plurality of memory chips, is to be input, and
the first status signal and the second status signal are output from one of the plurality of memory chips corresponding to the chip select signal.

19. The semiconductor storage device according to claim 15, wherein
each of the plurality of memory chips has a feature register in which chip select data that indicates a selected state or a non-selected state, is to be stored, and
the first status signal and the second status signal are output from one of the plurality of memory chips, in which the chip select data indicates the selected state.

20. A memory system comprising a controller and a memory chip that includes:
a first control signal pad to which a first control signal is to be input by the controller;
a second control signal pad to which a second control signal is to be input by the controller;
a data signal pad to and from which a data signal is to be input from the controller and output to the controller; and
a memory cell array including a plurality of memory cell transistors, wherein the memory chip
stores data in the data signal received through the data signal pad in a data register, when the controller sets the first control signal to be in a first state and the second control signal to be in the first state,
stores data in the data signal received through the data signal pad in a command register, when the controller sets the first control signal to be in a second state and the second control signal to be in the first state,
stores data in the data signal received through the data signal pad in an address register, when the controller sets the first control signal to be in the first state and the second control signal to be in the second state, and
outputs status data to the controller when the controller sets the first control signal to be in the second state and the second control signal to be in the second state.
